(19) United States
(12) Patent Application Publication
(10) Pub. No.: US 2014/0182674 A1
(43) Pub. Date: Jul. 3, 2014

(54) TRANSPARENT CONDUCTIVE FILM, METHOD OF PRODUCING THE SAME, FLEXIBLE ORGANIC ELECTRONIC DEVICE, AND ORGANIC THIN-FILM SOLAR BATTERY

(71) Applicant: FUJIFILM Corporation, Tokyo (JP)

(72) Inventors: Kohei HIGASHI, Kanagawa-ken (JP); Yoshiki MAEHARA, Kanagawa-ken (JP); Jiro TSUKAHARA, Kanagawa-ken (JP); Yuichi TOMARU, Kanagawa-ken (JP)

(73) Assignee: FUJIFILM CORPORATION, Tokyo (JP)

(21) Appl. No.: 14/196,144

(22) Filed: Mar. 4, 2014

Related U.S. Application Data
(63) Continuation of application No. PCT/JP2012/005510, filed on Aug. 31, 2012.

(30) Foreign Application Priority Data
Sep. 5, 2011 (JP) 2011-192869
Mar. 26, 2012 (JP) 2012-069123

(51) Int. Cl. H05K 1/02; H01L 31/18; H01L 31/0224

(52) U.S. Cl. CPC H05K 1/0274; H01L 31/022491; H01L 31/1884
USPC 136/256; 174/251; 29/846

(57) ABSTRACT

A transparent conductive film includes: a conductive stripe formed on a plastic support by a mask deposition process, the conductive stripe including a plurality of conductive lines made of a metal or an alloy having a film thickness of not less than 50 nm and not greater than 500 nm and a line width of not less than 0.3 mm and not greater than 1 mm in plan view and being arranged at an interval of not less than 3 mm and not greater than 20 mm; and a transparent conductive material layer formed to cover the plastic support and the conductive stripe, the transparent conductive material having a specific resistance of not greater than 4×10⁻³ Ω·cm and a film thickness of not less than 20 ma and not greater than 500 nm.

### TECHNICAL FIELD

The present invention relates to a transparent conductive film and a simple production method thereof, as well as an organic thin-film electronic device and an organic thin-film solar battery using the transparent conductive film.

### BACKGROUND ART

In recent years, flexible electronic devices as soft matters are attracting attention. In particular, there are higher and higher expectations for flexible organic electronic devices that are expected to achieve lightweight and low production cost, specifically, organic thin-film solar batteries and flexible organic EL devices (or organic electroluminescence devices).

A typical structure of flexible organic electronic devices includes an electron-conductive organic thin film and/or a hole-conductive organic thin film disposed between two dissimilar electrodes, at least one of which is transparent. Such flexible organic electronic devices have an advantage that the production thereof is easier than production of inorganic devices formed by using silicon, etc., thereby achieving lower production cost, and it is desired to put the flexible organic electronic devices into practical use.

In order to realize the flexible organic electronic device, a transparent conductive film having high transparency and high conductivity at the same time is required. A film with indium tin oxide (ITO) vapor-deposited thereon is widely known as a transparent conductive film having good performance; however, it has a problem of high cost.

On the other hand, each of Japanese Unexamined Patent Publication Nos. 2009-076668 and 2010-157681 (hereinafter, Patent Documents 1 and 2) discloses a transparent conductive film that is formed by a combination of a conductive metal mesh and a conductive polymer. In these prior art examples, a mask deposition process or a photoetching process is used to form the metal mesh.

Further, Y. Galagan et al., “ITO-free flexible organic solar cells with printed current collecting grids”, Solar Energy Materials & Solar Cells, Vol. 95, pp. 1339-1343, 2011 (hereinafter, Non-Patent Document 1) discloses a transparent conductive film that is formed by a combination of a screen-printed silver pattern and a conductive polymer, and an organic thin-film solar battery using the transparent conductive film.

### DISCLOSURE OF INVENTION

The production methods of the films disclosed in Patent Documents 1 and 2 are suitable for forming a sheet of film one by one. However, they are not suitable for a roll-to-roll production process, and they cannot sufficiently achieve the purpose of providing an inexpensive transparent conductive film.

The silver ink for screen printing disclosed in Non-Patent Document 1 contains a binder and requires heating at 140° C. for about five minutes to obtain sufficient conductivity. This is a problem with applying the silver ink to polyethylene terephthalate (PET), which is an inexpensive plastic substrate.

It is therefore desired to develop a transparent conductive film for organic electronic devices, the transparent conductive film being able to be formed on an inexpensive film substrate, as typified by PET, by a roll film-forming process and having high transparency and high conductivity at the same time.

A problem to be solved by the present invention is to provide a transparent conductive film for organic electronic devices, the transparent conductive film being able to be formed on an inexpensive film substrate by a roll film-forming process and having high transparency and high conductivity at the same time, and a method of producing the transparent conductive film.

Another problem to be solved by the invention is to provide an organic electronic device and an organic thin-film solar battery using the transparent conductive film.

The present inventors have found through intense study that the problems to be solved by the invention can be solved by a transparent conductive film including a conductive stripe made of a metal formed by a mask deposition process and a transparent conductive material having small specific resistance, thereby accomplishing the invention.

The constitution of the invention is as described below.

A transparent conductive film of the invention includes: a plastic support; a conductive stripe formed on the plastic support by a mask deposition process, the conductive stripe including a plurality of conductive lines made of a metal or an alloy having a film thickness of not less than 50 nm and not greater than 500 nm and a line width of not less than 0.3 mm and not greater than 1 mm in plan view and being arranged at an interval of not less than 3 mm and not greater than 20 mm; and a transparent conductive material layer formed to cover the plastic support and the conductive stripe, the transparent conductive material having a specific resistance of not greater than 4×10⁻³ Ω·cm and a film thickness of not less than 20 nm and not greater than 500 nm.

It is preferred that the conductive lines are made of silver or an alloy containing silver.

Alternatively, it is preferred that the conductive lines are made of copper or an alloy containing copper.

It is preferred that the conductive lines have a film thickness of not less than 100 nm and not greater than 300 nm.

It is preferred that the conductive lines of the conductive stripe are arranged at an interval of not less than 3 mm and not greater than 10 mm in plan view.

It is preferred that the conductive stripe has an open area ratio of not less than 80% and not greater than 95%.

The transparent conductive film of the invention may include a bus line that is in contact with the conductive stripe and has a line width of not less than 1 mm and not greater than 5 mm.

In particular, it is preferred that the bus line includes a plurality of bus lines, an interval between the bus lines is not less than 40 mm and not greater than 200 mm, and the bus lines are perpendicular to the conductive stripe.

It is preferred that the transparent conductive material layer is made of a transparent conductive polymer or a silver nanowire containing polymer.

It is preferred that the transparent conductive polymer is a doped polyethylenedioxythiophene.

A flexible organic electronic device of the invention includes a first electrode formed by the transparent conductive film of the invention, and a functional layer and a counter electrode formed in this order on the first electrode.

An organic thin-film solar battery of the invention includes a first electrode formed by the transparent conductive film of the invention, and a photoelectric conversion layer and a counter electrode formed in this order on the first electrode.

It is preferred that the organic thin-film solar battery of the invention includes an electron collection layer disposed between the photoelectric conversion layer and the counter electrode.

It is preferred that the electron-transporting layer is formed by a transparent inorganic oxide layer.

It is preferred that the transparent inorganic oxide layer contains titanium oxide or zinc oxide.

A first aspect of a method of producing a transparent conductive film of the invention includes the steps of: providing, on a roll of plastic support, a conductive stripe that is parallel to the longitudinal direction of the roll by a mask deposition process; and forming a transparent conductive material layer that covers the plastic support and the conductive stripe, wherein the steps are performed in this order.

A second aspect of the method of producing a transparent conductive film of the invention includes the steps of: providing, on a roll of plastic support, a conductive stripe that is parallel to the longitudinal direction of the roll by a mask deposition process; providing a bus line that is perpendicular to the conductive stripe; and forming a transparent conductive material layer that covers the conductive stripe and the bus line, wherein the steps are performed in this order.

A third aspect of the method of producing a transparent conductive film of the invention includes the steps of: providing, on a roll of plastic support, a bus line that is parallel to the width direction of the roll; providing a conductive stripe that is perpendicular to the bus line by a mask deposition process; and forming a transparent conductive material layer that covers the bus line and the conductive stripe, wherein the steps are performed in this order.

The transparent conductive film of the invention having the above-described constitution has good transparency and good conductivity. Therefore, use of the transparent conductive film of the invention as an electrode of an organic electronic device allows forming a good device.

The transparent conductive film of the invention is useful to produce an electronic device having good electric characteristics, in particular, a lightweight and flexible organic thin-film solar battery or organic EL device. An organic EL device using the transparent conductive film of the invention has excellent luminous efficiency, and an organic thin-film solar battery using the transparent conductive film of the invention has excellent power generation efficiency.

Using an optically transparent and flexible resin film as the support allows providing a flexible transparent conductive film. Such a flexible transparent conductive film allows producing a lightweight and flexible electronic device in a simple manner.

According to the method of producing a transparent conductive film of the invention, the conductive stripe and the bus line having a uniform composition can be formed at the same time, and this allows producing a transparent conductive film having excellent transparency and conductivity in a simple manner.

According to the invention, a transparent conductive film that has high transparency and high conductivity and a simple method for producing the transparent conductive film are provided.

Therefore, using the transparent conductive film of the invention allows providing an electronic device having good electric characteristics, such as an organic EL device having high luminous efficiency or an organic thin-film solar battery having good conversion efficiency.

### BRIEF DESCRIPTION OF THE DRAWINGS

FIG. 1 is a schematic sectional view illustrating a first embodiment of a transparent conductive film of the present invention,

FIG. 2 is a schematic plan view of the transparent conductive film shown in FIG. 1,

FIG. 3 is a schematic plan view illustrating a second embodiment of the transparent conductive film of the invention, and

FIG. 4 is a schematic sectional view illustrating one embodiment of an organic thin-film solar battery of the invention.

### DESCRIPTION OF PREPPED EMBODIMENTS

Hereinafter, the content of the present invention will be described in detail.

It should be noted that each numerical range expressed herein by a lower limit value and an upper limit value connected by “to” includes the lower limit value and the upper limit value.

### Transparent Conductive Film

First, a transparent conductive film of the invention is described.

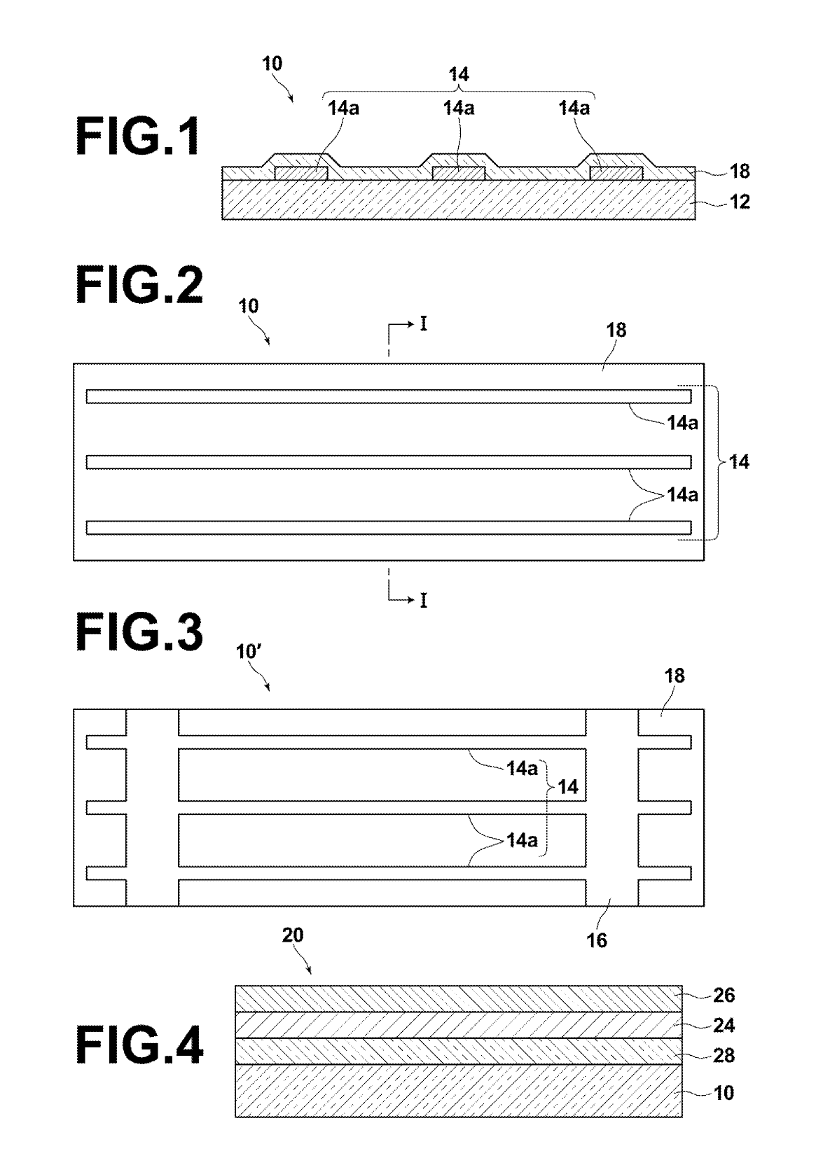

FIG. 1 is a schematic sectional view illustrating a first embodiment of the transparent conductive film of the invention, and

FIG. 2 is a schematic plan view of the transparent conductive film shown in FIG. 1.

As shown in FIGS. 1 and 2, a transparent conductive film 10 of this embodiment includes, on a plastic support 12, at least a conductive stripe 14, which includes a plurality of conductive lines 14a, and a transparent conductive material layer 18.

FIG. 3 is a schematic plan view illustrating a second embodiment of the transparent conductive film of the invention.

As shown in FIG. 3, a transparent conductive film 10′ of this embodiment includes, on the plastic support 12, at least the conductive stripe 14, which includes the plurality of conductive lines 14a, bus lines 16 and the transparent conductive material layer 18. The transparent conductive film 10′ of this embodiment differs from the first embodiment in that the transparent conductive film 10′ includes the bus lines 16. It should be noted that, in this embodiment, the bus lines 16 are formed to cross the conductive stripe 14.

The transparent conductive film of the invention may further include a known layer, such as an adhesion enhancing layer and a protective layer, as desired, as long as the transparent conductive film has the above-described structure and the advantageous effect of the invention is not impaired.

The transparent conductive film of the invention is suitably usable as a member forming an organic thin-film solar battery. In the case where the transparent conductive film of the invention is used to form an organic thin-film solar battery, the organic thin-film solar battery includes at least the transparent conductive film of the invention, a photoelectric conversion layer and a counter electrode. In this case, the transparent conductive film of the invention may be usable either as the positive electrode (cathode) or the negative electrode (anode); however, it is preferable to use the transparent conductive film as the positive electrode. It should be noted that, in the literature and patent documents in the art, element names of the electrodes of organic thin-film solar batteries are often opposite from those of the Stockholm convention, and one has to be careful. In the invention, the positive electrode of the battery is referred to as “cathode” and the negative electrode of the battery is referred to as “anode” according to the Stockholm convention.

The transparent conductive film of the invention is suitably usable as a member forming an organic EL device. In the case where the transparent conductive film of the invention is used to form an organic EL device, the organic EL device includes at least the transparent conductive film of the invention, a light-emitting layer, and a counter electrode. In this case, the transparent conductive film of the invention may be usable either as the positive electrode (anode) or the negative electrode (cathode); however, it is preferable to use the transparent conductive film as the positive electrode.

Now, details of the transparent conductive film of the invention are described.

### Plastic Support

The material, thickness, etc., of the plastic support 12 are not particularly limited and can be selected as appropriate depending on the purpose, as long as the plastic support can hold a conductive stripe, bus lines, a transparent conductive material layer, etc., which will be described later. An example of the support that is suitable for the transparent conductive film 10 is a support that is transparent to light in the wavelength range from 400 nm to 800 nm.

Specific examples of the material of the plastic support include thermoplastic resins, such as polyester resin, methacryl resin, methacrylate-maleate copolymer, polystyrene resin, transparent fluorine resin, polyimide, fluorinated polyimide resin, polyamide resin, polyamide-imide resin, polyetherimide resin, cellulose acylate resin, polyurethane resin, polyetheretherketone resin, polycarbonate resin, alicyclic polyolefin resin, polyarylate resin, polyethersulfone resin, polysulfone resin, cycloolefin copolymer, fluorene ring-modified polycarbonate resin, alicyclic modified polycarbonate resin, fluorene ring-modified polyester resin, acryloyl compound, etc.

The plastic support is preferably made of a heat-resisting material. Specifically, it is preferred that the plastic support is formed using a material that has heat resistance meeting at least one of the following physical properties: a glass transition temperature (Tg) of not lower than 60° C. and a linear thermal expansion coefficient of not higher than 40 ppm/° C., and is highly transparent to an exposure wavelength, as mentioned above.

It should be noted that the Tg and the linear expansion coefficient of the plastic support are measured according to the “Testing methods for transition temperatures of plastics” of JIS K 7121 and the “Testing method for linear thermal expansion coefficient of plastics by thermomechanical analysis” of JIS K 7197. Values of the Tg and the linear expansion coefficient of the plastic support used in the invention were measured according to these methods.

The Tg and the linear expansion coefficient of the plastic support can be adjusted using additives, etc. Examples of the highly heat-resistant thermoplastic resin include polyethylene terephthalate (PET: 65° C.), polyethylene naphthalate (PEN: 120° C.), polycarbonate (PC: 140° C.), alicyclic polyolefin (for example, ZEONOR 1600 available from Zeon Corporation: 160° C.), polyarylate (PAr: 210° C.), polyethersulfone (PES: 220° C.), polysulfone (PSF: 190° C.), cycloolefin copolymer (COC (a compound disclosed in Japanese Unexamined Patent Publication No. 2001-150584): 162° C.), fluorene ring-modified polycarbonate (BCF-PC (a compound disclosed in Japanese Unexamined Patent Publication No. 2000-227603): 225° C.), alicyclic modified polycarbonate (IP-PC (a compound disclosed in Japanese Unexamined Patent Publication No. 2000-227603): 205° C.), acryloyl compound (a compound disclosed in Japanese Unexamined Patent Publication No. 2002-080616: 300° C. or more), polyimide, etc. (In the above description, the numerical value shown together with the abbreviation, etc., of each resin in the parentheses is the Tg of the resin.) All the resins listed above are suitable for use as the base material in the invention. In particular, for applications where transparency is required, alicyclic polyolefin, or the like, is preferably used.

In the invention, the plastic support is required to be transparent to light. More specifically, the optical transmittance of the plastic film to light in the wavelength range from 400 nm to 1000 nm is preferably not less than 80%, more preferably not less than 85%, or even more preferably not less than 90%.

It should be noted that the optical transmittance can be found according to the method of JIS-K7105, namely, by measuring a total optical transmittance and an amount of scattered light using an integrating-sphere transmittance measuring device, and subtracting a diffuse transmittance from the total optical transmittance. Values of the optical transmittance used herein were calculated according to this method.

The thickness of the plastic support is not particularly limited; however, the thickness of the plastic support is typically in the range from 1 μm to 800 μm, and preferably in the range from 10 μm to 300 μm.

A known functional layer may be provided on the rear surface (on the side where the conductive stripe is not formed) of the plastic support. Examples of the functional layer include a gas barrier layer, a matting agent layer, an antireflection layer, a hard coating layer, an antifog layer, an antifouling layer, etc. Other functional layers are described in detail in paragraphs [0036] to [0038] of Japanese Unexamined Patent Publication No. 2006-289627.

### Adhesion Enhancing Layer/Undercoating Layer

The plastic support may include an adhesion enhancing layer or an undercoating layer.

The adhesion enhancing layer must contain a binder polymer, and may contain, as necessary, a matting agent, a surfactant, an antistatic agent, particulates for controlling refractive index, etc.

The binder polymer used in the adhesion enhancing layer is not particularly limited, and may be selected, as appropriate, from the following acrylic resins, polyurethane resins, polyester resins and rubber resins, for example.

Acrylic resins are polymers composed of acrylic acid, methacrylic acid or derivatives thereof. Specific examples thereof include polymers composed mainly of acrylic acid, methacrylic acid, methylmethacrylate, ethylacrylate, butylacrylate, 2-ethylhexylacrylate, acrylamide, acrylonitrile, hydroxyl acrylate, etc., and formed through copolymerization between these compounds and a monomer (such as styrene, divinylbenzene, etc.) that is copolymerizable with these compounds.

Polyurethane resin is the collective term for polymers having urethane bonds in the main chain, which are typically obtained through a reaction between a polyisocyanate and a polyol. Examples of the polyisocyanate include TDI (Tolylene Diisocyanate), MDI (Methyl Diphenyl Isocyanate), HDI (Hexylene diisocyanate), IPDI (Isophoron diisocyanate), etc. Examples of the polyol include ethylene glycol, propylene glycol, glycerin, hexanetriol, trimethylolpropane, pentaerythritol, etc. Further, as the isocyanate of the invention, a polymer obtained by performing chain extension to increase the molecular weight on a polyurethane polymer that is obtained through a reaction between a polyisocyanate and a polyol may also be usable.

Polyester resin is the collective term for polymers having ester bonds in the main chain, which are typically obtained through a reaction between a polycarboxylic acid and a polyol. Examples of the polycarboxylic acid includes fumaric acid, itaconic acid, adipic acid, sebacic acid, terephthalic acid, isophthalic acid, naphthalenedicarboxylic acid, etc. Examples of the polyol are as described above.

The rubber resin of the invention refers to a diene synthetic rubber among synthetic rubbers. Specific examples of the diene synthetic rubber include polybutadiene, styrene-butadiene copolymer, styrene-butadiene-acrylonitrile copolymer, styrene-butadiene-divinylbenzene copolymer, butadiene-acrylonitrile copolymer, polychloroprene, etc.

The thickness of coating of the adhesion enhancing layer or the undercoating layer after drying is preferably in the range from 50 nm to 2 μm. If the layer has a layered structure, it is preferable that the total thickness of layers forming the layered structure is within the above range.

It should be noted that, if the support is used as a tentative support, a treatment to make the support easily peelable may be applied to the surface of the support.

### Conductive Stripe

The conductive stripe 14 of the invention is formed by a mask deposition process to have a film thickness of the conductive lines 14a of not less than 50 nm and not greater than 500 nm, a line width of not less than 0.3 mm and not greater than 1 mm in plan view, and a line interval of not less than 3 mm and not greater than 20 mm. The film thickness is preferably not less than 100 nm and not greater than 300 nm, and the line interval is preferably not less than 3 mm and not greater than 10 mm.

The design of the stripe is adjusted to provide desired values of the open area ratio (optical transmittance) and the conductivity. The open area ratio defined by the conductive stripe (an area found by subtracting an area of the conductive stripe in plan view from a film area (an area occupied by the conductive lines in plan view)/the film area) is not less than 70% and not greater than 99%, preferably not less than 75%, or more preferably not less than 80%. Since there is a trade-off between the optical transmittance and the conductivity, a greater open area ratio is more preferable. However, practically, the open area ratio is not greater than 95%.

Each conductive line forming the conductive stripe has a resistance value of not greater than 50 Ω/cm, preferably not greater than 20 Ω/cm, or more preferably not greater than 10 Ω/cm. In order to achieve this level of conductivity (i.e., low resistance), the metal material needs to have a small value of the specific resistance and each conductive stripe line needs to have a large sectional area. In order to provide a large open area ratio, a cross-sectional shape with a short length in the film-plane direction (line width) and a long length in the film-thickness direction (film thickness) is advantageous.

However, providing the conductive stripe having the above-described cross-section results in large height difference. Since the thickness of the active layer (organic layer) of an organic electronic device is as thin as 50 to 500 nm, the large height difference due to the conductive stripe is likely to cause short circuit (failure) at corners of the protrusions of the conductive stripe lines.

Therefore, it is more important to reduce the height difference due to the conductive stripe and make the corners of the protrusions of the conductive stripe lines obtuse than to increase the open area ratio, and a design where the open area ratio is somewhat sacrificed have to be adopted. Namely, a design where the cross-sectional shape has a large line width and a small film thickness is selected. The ratio between the line width and the film thickness is in the range from 20000:1 to 200:1. As the film thickness, a value of the thickest part of the line in the line width direction is used.

Depending on the method for forming the stripe, the cross-sectional shape of the conductive lines can be a rectangle, an isosceles trapezoid, an obtuse isosceles triangle, a semicircle, a figure enclosed in an arc and a chord, a deformed figure of any of these shapes, or the like. An isosceles trapezoid or an obtuse isosceles triangle, which are tapered shapes, are less likely to cause short circuit and are more preferable than a cross-sectional shape with right-angle corners of the protrusion of the line, such as a rectangle. Also, a curved or sloped cross-sectional shape with smoothed height difference is less likely to cause short circuit and is more preferable than a cross-sectional shape with clear-cut corners.

In view of device characteristics (such as current-voltage characteristics), a smaller interval (pitch) between the lines 14a of the conductive stripe 14 is more advantageous. However, a smaller pitch means a smaller open area ratio, and therefore a point of compromise is selected. The pitch is determined to provide a preferred open area ratio depending on the line width of the metal thin lines.

Since the transparent conductive film of the invention is for an organic electronic device and since the design where the open area ratio is sacrificed is adopted with respect to the relationship between the film thickness and the line width of the conductive stripe, a pitch of the conductive stripe that provides a maximum open area ratio is required. Namely, in order to ensure an open area ratio of 75% when the line width of the conductive stripe is 1 mm, a pitch of not less than 3 mm is required.

The present inventors have found through study that, at least for use with an organic thin-film solar battery, a highly conductive transparent conductive material that has a specific resistance value of not greater than 4×10⁻³ Ω·cm is required. This point will be described later with respect to the transparent conductive material.

The material forming the conductive stripe 14 is a metal or an alloy having a specific resistance of not greater than 1×10⁻⁵Ω·cm. Examples of the metal or alloy include gold, platinum, iron, copper, silver, aluminum, chromium, cobalt, silver, and alloys containing these metals. More preferred examples of the metal or alloy include low resistance metals, such as copper, silver and gold, and alloys containing these low resistance metals. Among them, silver, alloys containing silver, copper and alloys containing copper are particularly preferred.

### Formation of Conductive Stripe

The conductive stripe of the invention is formed by a mask deposition process. As the mask deposition process, a known method can be used. The mask deposition process is advantageous in that it is a production method that best develops the conductivity of a metal, that it does not requires a heating step after the production, and that it is easy to provide obtuse corners of protrusions of the cross-section of the stripe lines, which are less likely to cause short circuit in the organic thin film device.

Namely, a greater thickness of the mask used or a greater distance between the mask and the film results in more obtuse corners of the protrusions, i.e., a more preferable cross-sectional shape of the stripe lines formed by the mask deposition process. Further, in a case where the mask deposition process is performed while the film is conveyed with a roll-to-roll system, a cross-sectional shape with obtuse corners is naturally provided due to fluctuation in the width direction during the conveyance.

The shape of the openings of the mask can also be adapted to provide obtuse corners. For example, if the shape of each opening of the mask is a rectangle having longer sides in the conveyance direction, obtuse corners of the protrusions can be provided by setting the longer sides of the rectangle slightly non-parallel to the conveyance direction.

### Bus Lines

The transparent conductive film of the invention may include, on the support, the bus lines (thick-line conductive layer) 16, which cross the conductive stripe 14.

In view of ensuring the conductivity necessary for the entire operating surface, the bus lines 16 are wiring having a line width of not less than 1 mm and not greater than 5 mm in plan view. The line width of the bus lines is preferably not less than 1 mm and not greater than 3 mm.

The line width of the bus lines 16 may not necessarily be uniform. The bus lines and the conductive stripe may be made of the same material or different materials. Usually, the bus lines are formed to be perpendicular to the conductive stripe; however, the bus lines may cross the conductive stripe at an angle other than 90°. The preferred thickness, cross-sectional shape and material of the bus lines are the same as those described with respect to the conductive stripe.

As the interval (pitch) of the bus lines, an optimum condition at a point of compromise between the conductivity and the optical transmittance of a large area is selected, similarly to the conductive stripe. Specifically, the interval of the bus lines is determined by the conductivity of the conductive stripe connecting the bus lines adjacent to each other. Typically, the interval is selected such that the resistance value of the conductive stripe connecting two adjacent bus lines is not greater than 50Ω per line. The resistance value is preferably not greater than 20Ω, or particularly preferably not greater than 10 Ω.

The pitch of the bus lines is preferably not less than 40 mm and not greater than 200 mm.

### Formation of Bus Lines

In the invention, the bus lines 16 may be formed by vapor deposition, or by printing or inkjet printing. In view of costs, it is advantageous to form the conductive stripe 14 and the bus lines 16 at the same time using a material of the same composition. In a case where the conductive stripe 14 and the bus lines 16 are formed at the same time by a mask deposition process using a roll-to-roll system, equipment including a fixed mask for forming the stripe and a movable mask for forming the bus lines is necessary.

### Transparent Conductive Material Layer

The transparent conductive material layer 18 of the invention is required to be transparent to a range of an emission spectrum or an action spectrum of an organic electronic device to which the transparent conductive film 10 of the invention is applied, and is usually required to have excellent optical transparency to light in the range from visible light to near-infrared light. Specifically, when a layer of a transparent conductive material having a thickness of 0.1 μm is formed, the formed layer has an average optical transmittance in the wavelength range from 400 nm to 800 nm of not less than 50%, preferably not less than 75%, or more preferably not less than 85%.

The transparent conductive material layer 18 is disposed to be in contact with the conductive stripe 14 (or the conductive stripe 14 and the bus lines 16 in the case where the bus lines 16 are provided) and cover the surface thereof. The transparent conductive material layer 18 has a thickness in the range from 20 to 500 nm, preferably in the range from 30 to 300 nm, or more preferably in the range from 50 to 200 nm.

The transparent conductive material used in the invention has a specific resistance after film formation of not greater than 4×10⁻³ Ω·cm. In the case where it is desired to use the transparent conductive material having a thickness in the range from 20 to 500 nm or preferably in the range from 50 to 200 nm and the conductive stripe having a pitch not less than 3 mm, it is required to achieve the above specific resistance.

Examples of the transparent conductive material having such a specific resistance include a dispersion of a conductive nanomaterial (such as silver nanowire, carbon nanotube, graphene, etc.) in an acrylic polymer, or the like, and conductive polymers (such as polythiophene, polypyrrol, polyaniline, polyphenylenevinylene, polyphenylene, polyacethylene, polyquinoxaline, polyoxadiazole, polybenzothiadiazole, etc., and polymers having two or more of these conductive skeletons, etc.)

Among them, polythiophene is preferable, and polyethylenedioxythiophene is particularly preferable. These polythiophenes are usually subjected to partial oxidation to provide conductivity. The conductivity of conductive polymers can be adjusted by the degree of partial oxidation (amount of doping). The larger the amount of doping, the higher the conductivity. Polythiophenes become cationic through the partial oxidation and therefore have a counter anion to neutralize the charge. An example of such a polythiophene is polyethylenedioxythiophene with polystyrene sulfonate as the counter ion (PEDOT-PSS). The PEDOT-PSS may contain a high-boiling point organic solvent in order to increase the conductivity. Examples of the high-boiling point organic solvent include ethylene glycol, diethylene glycol, dimethylsulfoxide, N-methylpyrrolidone, 1,3-dimethyl-2-imidazolidinone, etc.

A specific example of commercially-available PEDOT-PSS products that achieve the above-described specific resistance is ORGACON S-305 available from Agfa.

The transparent conductive material layer 18 may contain other polymers, as long as the desired conductivity is not impaired. The purposes of adding other polymers are to improve ease of coating and to increase the film strength.

Examples of the other polymers include thermoplastic resins, such as polyester resin, methacryl resin, methacrylate-maleate copolymer, polystyrene resin, transparent fluorine resin, polyimide, fluorinated polyimide resin, polyamide resin, polyamide-imide resin, polyetherimide resin, cellulose acylate resin, polyurethane resin, polyetheretherketone resin, polycarbonate resin, alicyclic polyolefin resin, polyarylate resin, polyethersulfone resin, polysulfone resin, cycloolefin copolymer, fluorene ring-modified polycarbonate resin, alicyclic modified polycarbonate resin, fluorene ring-modified polyester resin, acryloyl compound, etc., and hydrophilic polymers, such as gelatin, polyvinyl alcohol, polyacrylic acid, polyacrylamide, polyvinyl pyrrolidone, polyvinyl pyridine, polyvinyl imidazole, etc. These polymers may have a crosslinked structure to increase the film strength.

The transparent conductive material is often in the form of an aqueous solution or aqueous dispersion. Therefore, a common aqueous coating process is used to form the layer. The coating solution may include, as coating aids, various solvents, a surfactant, a thickener, etc.

In the invention, a first electrode including the conductive stripe 14 and the transparent conductive material layer 18 may function as the positive electrode (anode) of an organic EL device or the positive electrode (cathode) of an organic thin-film solar battery.

### Method of Producing Transparent Conductive Film

The method of producing the transparent conductive film 10 shown in FIG. 1 includes: a (conductive stripe forming) step of providing, on a roll of plastic support, the conductive stripe that is parallel to the longitudinal direction of the roll by a mask deposition process; and a step of forming the transparent conductive material layer that covers the plastic support and the conductive stripe, where the steps are performed in this order.

The method of producing the transparent conductive film 10′ shown in FIG. 3 includes: a (conductive stripe forming) step of providing, on a roll of plastic support, the conductive stripe that is parallel to the longitudinal direction of the roll by a mask deposition process; a (bus line forming) step of providing the bus lines that are perpendicular to the conductive stripe; and a step of forming the transparent conductive material layer that covers the conductive stripe and the bus lines, where the steps are performed in this order.

Alternatively, the method of producing the transparent conductive film 10′ shown in FIG. 3 may include: a (bus line forming) step of providing, on a roll of plastic support, the bus lines that are parallel to the width direction of the roll; a (conductive stripe forming) step of providing the conductive stripe that is perpendicular to the bus lines by a mask deposition process; and a step of forming the transparent conductive material layer that covers the bus lines and the conductive stripe, where the steps are performed in this order.

The thus produced transparent conductive film of the invention is suitable for a flexible organic electronic device. In particular, in the case of an organic thin-film solar battery, the conductivity of the transparent conductive film is directly linked to the power generation efficiency, and therefore the advantageous effect of the invention is remarkably exhibited. Now, an organic thin-film solar battery using the transparent conductive film of the invention (which may hereinafter be referred to as “organic thin-film solar battery of the invention”) is described in detail.

### Organic Thin-Film Solar Battery

FIG. 4 is a sectional view illustrating the schematic structure of one embodiment of an organic thin-film solar battery 20 of the invention.

As shown in FIG. 4, the organic thin-film solar battery 20 of the invention includes the transparent conductive film 10 of the invention serving as one of the electrodes, and at least a photoelectric conversion layer 24 and a counter electrode (second electrode) 26 formed in layers on the transparent conductive film 10.

In the organic thin-film solar battery 20 of the invention, the transparent conductive film 10 may be used either as the positive electrode or the negative electrode. The polarity of the counter electrode 26 is opposite from that of the transparent conductive film 10. Namely, if the transparent conductive film 10 is used as the positive electrode, the counter electrode 26 is the negative electrode. If the transparent conductive film 10 is used as the negative electrode, the counter electrode 26 is the positive electrode.

A preferred example of the layer structure of the organic thin-film solar battery of the invention includes the transparent conductive film 10 of the invention serving as the positive electrode, and an electron-blocking layer 28, the photoelectric conversion layer 24, an electron collection layer (not shown) and the counter electrode 26 formed in layers on the transparent conductive film 10.

### Electron-Blocking Layer

It is preferred that the electron-blocking layer 28 is provided between the transparent conductive film (positive electrode) 10, which has the transparent conductive material layer, and the photoelectric conversion layer (for example, a bulk hetero layer) 24. The electron-blocking layer 28 has a function of blocking migration of electrons from the photoelectric conversion layer (for example, a bulk hetero layer) 24 to the positive electrode 10. As a material having the function of blocking migration of electrons, an inorganic semiconductor called a p-type semiconductor or an organic compound called a hole-transporting material is used. More specific examples of the material having the function of blocking migration of electrons include a metal oxide having a valence band level of not greater than 5.5 eV and a conduction band level of not greater than 3.3 eV, or an organic compound having a HOMO level of not greater than 5.5 eV and a LUMO level of not greater than 3.3 eV.

### Metal Oxide Used in Electron-Blocking Layer

Specific examples of the metal oxide usable in the electron-blocking layer include molybdenum oxide, vanadium oxide, etc.

In the case where the electron-blocking layer 28 is formed using the metal oxide, usually a gas-phase process, such as vapor deposition, is applied.

### Organic Compound Used in Electron-Blocking Layer

Specific examples of the organic compound usable in the electron-blocking layer include aromatic amine derivatives, thiophene derivatives, condensed aromatic compounds, carbazole derivatives, polyanilines, polythiophenes, polypyrrols, etc. Besides them, a group of compounds disclosed as “Hole Transport material” in Chem. Rev., Vol. 107, pp. 953-1010, 2007 is also applicable.

Among them, polythiophenes are preferable, and polyethylenedioxythiophene is more preferable. The polyethylenedioxythiophene may be subjected to doping (partial oxidation), as long as a volume resistance of not lower than 10 Ωcm is maintained. In this case, the polyethylenedioxythiophene may have a counter anion derived from a perchloric acid, a polystyrene sulfonate, or the like, to neutralize the charge.

As the material used to form the electron-blocking layer, molybdenum oxide or polythiophene is preferable, or molybdenum oxide or polyethylenedioxythiophene is more preferable.

As the thickness of the electron-blocking layer 28, it is necessary to select a sufficient thickness to suppress leakage of electrons from the electron-transporting material present in the bulk hetero-type photoelectric conversion layer to the transparent conductive material layer 18 forming the first electrode. In this view, the thickness is preferably not less than 0.1 nm. The upper limit of the thickness is not particularly limited; however, in view of production efficiency, the thickness is preferably not greater than 50 nm. More preferably, the thickness is in the range from 1 nm to 20 nm.

In a case where the transparent conductive material used to form the transparent conductive film of the invention is a polythiophene, the electron-blocking layer can be omitted.

### Photoelectric Conversion Layer

The photoelectric conversion layer 24 may have a planar heterostructure including a hole-transporting layer and an electron-transporting layer, or a bulk heterostructure made of a mixture of a hole-transporting material and an electron-transporting material. In the case where the photoelectric conversion layer has a planar heterostructure, the hole-transporting layer is located on the positive electrode side and the electron-transporting layer is located on the negative electrode side. Alternatively, the photoelectric conversion layer may have a hybrid structure including a bulk hetero layer as an intermediate layer in a planar heterostructure.

The hole-transporting layer contains a hole-transporting material.

The hole-transporting material is a n electron conjugated compound having a HOMO level in the range from 4.5 eV to 6.0 eV. Specific examples thereof include conjugated polymers coupled with various arenes (suchasthiophene, carbazole, fluorene, silafluorene, thienopyrazine, thienobenzothiophene, dithienosilole, quinoxaline, benzothiadiazole, thienothiophene, etc.), phenylenevinylene polymers, porphyrins, phthalocyanines, etc. Besides them, a group of compounds disclosed as “Hole Transport material” in Chem. Rev., Vol. 107, pp. 953-1010, 2007 and porphyrin derivatives disclosed in Journal of the American Chemical Society, Vol. 131, p. 16048, 2009 are also applicable.

Among them, conjugated polymers coupled with a building block selected from the group consisting of thiophene, carbazole, fluorene, silafluorene, thienopyrazine, thienobenzothiophene, dithienosilole, quinoxaline, benzothiadiazole and thienothiophene are particularly preferable. Specific examples thereof include poly3-hexylthiophene, poly3-octylthiophene, various polythiophene derivatives disclosed in Journal of the American Chemical Society, Vol. 130, p. 3020, 2008, PCDTBT disclosed in Advanced Materials, Vol. 19, p. 2295, 2007, PCDTQx, PCDTPP, PCDTPT, PCDTBX and PCDTPX disclosed in Journal of the American Chemical Society, Vol. 130, p. 732, 2008, PBDTTT-E, PBDTTT-C and PBDTTT-CF disclosed in Nature Photonics, Vol. 3, p. 649, 2009 and PTB7 disclosed in Advanced Materials, Vol. 22, pp. 1-4, 2010.

The thickness of the hole-transporting layer is preferably in the range from 5 to 500 nm, or particularly preferably in the range from 10 to 200 nm.

The electron-transporting layer is made of an electron-transporting material. The electron-transporting material is a n electron conjugated compound having a LUMO level in the range from 3.5 eV to 4.5 eV. Specific examples thereof include fullerenes and derivatives thereof, phenylenevinylene polymers, naphthalenetetracarboxylic imide derivatives, perylenetetracarboxylic imide derivatives, etc. Among them, fullerene derivatives are preferable. Specific examples of the fullerene derivatives include C₆₀, phenyl-C₆₁-methyl acetate (a fullerene derivative called PCBM, [60] PCBM or PC₆₁BM in the literature), C₇₀, phenyl-C₇₁-methyl acetate (a fullerene derivative often called PCBM, [70] PCBM or PC₇₁BM in the literature), fullerene derivatives disclosed in Advanced Functional Materials, Vol. 19, pp. 779-788, 2009 and a fullerene derivative SIMEF disclosed in Journal of the American Chemical Society, Vol. 131, p. 16048, 2009.

The thickness of electron-transporting layer is preferably in the range from 5 to 500 nm, or particularly preferably in the range from 10 to 200 nm.

The bulk hetero-type photoelectric conversion layer (which may hereinafter be referred to as “bulk hetero layer”) 24 is an organic photoelectric conversion layer containing a mixture of a hole-transporting material and an electron-transporting material. The mixing ratio between the hole-transporting material and the electron-transporting material contained in the bulk hetero layer 24 is adjusted such that the maximum conversion efficiency is achieved. The mixing ratio between the hole-transporting material and the electron-transporting material is usually selected to be in the range from 10:90 to 90:10 in mass ratio. Formation of such a mixed organic layer may be achieved, for example, by a vacuum co-evaporation method. Alternatively, formation of the mixed organic layer may be achieved by solvent coating using a solvent in which both the organic materials, i.e., the hole-transporting material and the electron-transporting material dissolve. A specific example of the solvent coating will be described later.

The thickness of the bulk hetero layer 24 is preferably in the range from 10 nm to 500 nm, or particularly preferably in the range from 20 nm to 300 nm.

The hole-transporting material and the electron-transporting material in the bulk hetero layer may be mixed completely uniformly, or may be phase-separated with a domain size in the range from 1 nm to 1 μm. The phase-separated structure may be a random structure or an ordered structure. When an ordered structure is formed, formation of the ordered structure may be achieved by a top-down approach, such as nanoimprinting, or a bottom-up approach, such as self-organization. Examples of the hole-transporting material and the electron-transporting material used in the bulk hetero layer are the same as those described above with respect to the hole-transporting layer and the electron-transporting layer.

### Electron Collection Layer

The organic thin-film solar battery of the invention may include an electron collection layer made of an electron-transporting material, as necessary. Examples of the electron-transporting material usable to form the electron collection layer include the materials forming the electron-transporting layer described above with respect to the photoelectric conversion layer, materials disclosed as “Electron Transport Materials” in Chem. Rev., Vol. 107, pp. 953-1010, 2007 and an n-type transparent inorganic oxide having electron-transporting ability (such as titanium oxide, zinc oxide, tin oxide, tungsten oxide, etc.) Among them, titanium oxide and zinc oxide are preferable.

The thickness of the electron collection layer is in the range from 1 nm to 30 nm, and preferably in the range from 2 nm to 15 nm. The electron collection layer can be preferably formed by any of various wet film-forming methods, dry film-forming methods, such as vapor deposition or sputtering, a transfer method, printing, etc. In particular, a method of forming a zinc oxide layer disclosed in Journal of Physical Chemistry C, Vol. 114, pp. 6849-6853, 2010 and methods of forming a titanium oxide layer disclosed in Thin Solid Film, Vol. 517, pp. 3766-3769, 2007 and in Advanced Materials, Vol. 19, pp. 2445-2449, 2007 are particularly preferable.

### Negative Electrode (Second Electrode)

Usually, the negative electrode 26 is only required to have a function of receiving electrons from the electron-transporting layer or the electron collection layer. The shape, structure, size, etc., of the negative electrode 26 are not particularly limited. The material of the negative electrode 26 can be selected as appropriate from known electrode materials depending on the use and the purpose of the solar battery device. Examples of the material forming the negative electrode include metals, alloys, inorganic oxides doped with an impurity, inorganic nitrides, and other electroconductive compounds (such as graphite, carbon nanotube, etc.) These materials may be used alone or in combination of two or more.

Specific examples of the metals and alloys usable to form the negative electrode include silver, copper, aluminum, magnesium, silver-magnesium alloy, etc.

Examples of the inorganic oxide doped with an impurity include titanium oxide, zinc oxide, tin oxide and tungsten oxide. The purpose of the impurity doping is to increase the carrier density in the oxide to increase the conductivity. An element to be doped is a metal element of a group on the immediate right of the metal element of the inorganic oxide on the periodic table or a halogen element. For example, with respect to titanium oxide, a group 5 element, such as niobium or tantalum may be doped, or a halogen (such as fluorine or chlorine) is doped. With respect to zinc oxide, a group 13 element, such as boron, aluminum, gallium or indium may be doped, or a halogen may be doped. With respect to tin oxide, usually fluorine is doped. The inorganic oxide doped with an impurity may be crystalline or amorphous.

The thickness of the negative electrode is in the range from 10 nm to 500 nm, or preferably in the range from 50 nm to 300 nm. Formation of the oxide semiconductor layer can be achieved by any of various wet film-forming methods, dry film-forming methods, such as vapor deposition or sputtering, a transfer method, printing, etc. Among them, vapor deposition or sputtering is preferable.

Patterning during the formation of the negative electrode may be achieved by chemical etching, such as photolithography, physical etching using a laser, or the like, or vacuum deposition or sputtering using layers of masks.

In the invention, the position where the negative electrode is formed is not particularly limited. The negative electrode may be formed on the entire organic layer or part of the organic layer. In the case where the negative electrode is made of a transparent material, negative electrode bus lines that are in contact with the negative electrode may be provided above and below the negative electrode.

### Negative Electrode Bus Lines

The negative electrode bus lines are designed to increase the conductivity of the negative electrode across the entire surface of the solar battery.

### Other Organic Layers

In the invention, auxiliary layers, such as a hole-blocking layer, an exciton diffusion preventing layer, etc., may be provided, as necessary. In the invention, the term “organic layer” is used to collectively refer to layers using an organic compound, such as the bulk hetero layer, the hole-transporting layer, the electron-transporting layer, the electron-blocking layer, the hole-blocking layer, the exciton diffusion preventing layer, etc.

### Annealing

The organic thin-film solar battery of the invention may be annealed using any of various methods in order to crystallize the organic layer and promote the phase separation of the bulk hetero layer. Examples of the annealing method include a method where the substrate temperature during vapor deposition is elevated by heating to a temperature in the range from 50° C. to 150° C., a method where the drying temperature after coating is set at a temperature in the range from 50° C. to 150° C., etc. Alternatively, the annealing may be achieved by heating at a temperature in the range from 50° C. to 150° C. after the formation of the second electrode.

### Protective Layer

The organic thin-film solar battery of the invention may be protected by a protective layer. In particular, forming the protective layer on the negative electrode or the negative electrode provided with the bus lines, as desired, is preferable in view of preventing corrosion of the negative electrode. Examples of the material contained in the protective layer include a metal oxide, such as MgO, SiO, SiO₂, Al₂O₃, Y₂O₃ or TiO₂, a metal nitride, such as SiNₓ, a metal nitride oxide, such as SiNₓO_{y}, a metal fluoride, such as MgF₂, LiF, AlF₃ or CaF₂, or a polymer, such as polyethylene, polypropylene, polyvinylidene fluoride or polyparaxylylene. Among them, an oxide, a nitride or a nitride oxide of a metal is preferable, and an oxide, a nitride or a nitride oxide of silicon or aluminum are particularly preferable. The protective layer may be a single layer or a multi-layer structure.

The method for forming the protective layer is not particularly limited. For example, vacuum deposition, sputtering, reactive sputtering, MBE (molecular beam epitaxy), cluster ion beam, ion plating, plasma polymerization (high-frequency excitation ion plating), plasma CVD, laser CVD, thermal CVD, gas source CVD, vacuum ultraviolet CVD, coating, printing or a transfer method is applicable.

### Gas Barrier Layer

The organic thin-film solar battery of the invention may include a gas barrier layer. The gas barrier layer is not particularly limited as long as it has the gas barrier ability. Usually, the gas barrier layer is a layer of an inorganic material (which may also be referred to as “inorganic layer”). Typical examples of the inorganic material contained in the inorganic layer include an oxide, a nitride, an oxynitride, a carbide, a hydride, etc., of boron, magnesium, aluminum, silicon, titanium, zinc and tin. The inorganic material may be a pure material, or a mixture or a gradient material layer including different compositions. Among them, an oxide, a nitride or an oxynitride of aluminum, or an oxide, a nitride or an oxynitride of silicon is preferable.

The inorganic layer serving as the gas barrier layer may be a single layer or a layered structure. In the case where the gas barrier layer has a layered structure, the layered structure may include an inorganic layer and an organic layer, or a plurality of inorganic layers and a plurality of organic layer that are alternately disposed, as long as the gas barrier ability is not impaired. An organic layer that may be included in the gas barrier layer having a layered structure is not particularly limited, as long as it is a smooth layer, and a preferred example thereof is a layer made of a (meth) acrylate polymer.

The thickness of the inorganic layer serving as the gas barrier layer is not particularly limited; however, it is usually in the range from 5 to 500 nm per layer, or preferably in the range from 10 to 200 nm per layer. The inorganic layer may have a layered structure including a plurality of sub-layers. In this case, the sub-layers may have the same composition or different compositions. Alternatively, as mentioned above, a layer without a clear interface between the inorganic layer and the organic polymer layer adjacent to each other, where one of different compositions changes over to the other of the compositions in a continuous manner in the thickness direction, as disclosed in U.S. Patent Application Publication No. 2004046497, may be applied.

The thickness of the organic thin-layer solar battery of the invention is preferably in the range from 50 μm to 1 mm, or more preferably in the range from 100 μm to 500 μm.

In a case where a solar battery module is produced using the organic thin-layer solar battery of the invention, teachings in HAMAKAWA Yoshihiro, Taiyoko Hatsuden—Saishin-no-Gijutsu-to-Sisutemu (Photovoltaic Power Generation—the Latest Technology and System) (published by CMC Publishing Co., Ltd.), etc., can be referenced.

### EXAMPLES

Hereinafter, the present invention is more specifically described using examples. The materials, amounts of the materials used, ratios, contents of treatments, procedures, etc., shown in the following examples can be modified as appropriate without departing from the spirit of the invention. Therefore, the scope of the invention is not limited to the specific examples shown below.

### Examples 1 to 3 and Comparative Examples 1 and 2

### Production of Transparent Conductive Film

The conductive stripe was formed on a polyethylene terephthalate film (which will hereinafter be abbreviated as “PET film”) having a thickness of 180 μm, and the conductive polymer layer was formed on the conductive stripe to produce a transparent conductive film (F-1 to F-5)

### Formation of Conductive Stripe

Each piece of PET film cut into a size of 25 mm×25 mm and a mask for a 25 mm×25 mm substrate were set in a vacuum deposition apparatus, and silver was vapor-deposited to the thickness shown in Table 1 using resistance heating. The vapor deposition was upward deposition, and the deposition pattern was a parallel stripe having a line width of 0.5 rum, a line length of 20 mm and the line interval shown in Table 1. To form this pattern, the mask made of stainless-steel and having a thickness of 0.2 mm was set above the PET film with a clearance of 1 mm.

Subsequently, contact between ends of the conductive stripe was provided using a silver paste to form a silver stripe film.

### Formation of Conductive Polymer Layer

On the surface of the thus formed film, an aqueous dispersion of polyethylenedioxythiophene/polystyrene sulfonate (abbreviated as PEDOT-PSS) (ORGACON S-305, available from Agfa) was spin-coated. Then, this film was dried by heating at 110° C. for 20 minutes to form a conductive polymer layer. The thickness of the conductive polymer layer was 100 nm.

In this manner, each transparent conductive film (F-1 to F-5) having the conductive stripe having the thickness, the line width and the interval shown in Table 1 was obtained. The transparent conductive films F-1 to F-3 are Examples 1 to 3 of the invention, and the transparent conductive films F-4 and F-5 are Comparative Examples 1 and 2.

### Example 1-2

### Formation of Conductive Stripe

A copper stripe film was produced in the same manner as in Example 1 (the transparent conductive film F-1), except that the metal material forming the conductive stripe was changed from silver to copper.

### Formation of Conductive Polymer Layer

On the surface of the thus formed film, an aqueous dispersion of polyethylenedioxythiophene/polystyrene sulfonate (abbreviated as PEDOT-PSS) (ORGACON S-305, available from Agfa) was spin-coated. Then, this film was dried by heating at 110° C. for 20 minutes to form a conductive polymer layer. The thickness of the conductive polymer layer was 100 nm.

In this manner, a transparent conductive film (F-6) of Example 1-2 shown in Table 1 was obtained.

Separately from this, the conductive polymer layer was formed in the same manner as described above on a 25 mm×25 mm PET film without the conductive stripe vapor-deposited thereon, and the surface resistance value was found to be 220Ω/□. Based on this result, the specific resistance of the transparent conductive material layer 18 of F-1 was calculated to be 2.2×10⁻³Ω·cm. The measurement of the surface resistance was performed according to JIS7194 using a resistivity meter, LORESTA GP/ASP probe, available from Mitsubishi Chemical Corporation.

### Production of Organic Thin-Film Solar Battery

On each of the transparent conductive films (F-1 to F-5) produced as described above, the photoelectric conversion layer 24 and the counter electrode (negative electrode) 26 were formed to produce organic thin-film solar batteries (P-1 to P-5). With respect to the transparent conductive film (F-6) produced as described above, the electron-blocking layer 28 was formed before the photoelectric conversion layer 24 was formed.

### Formation of Electron-Blocking Layer

On the conductive polymer layer of the transparent conductive film (F-6), an aqueous dispersion of polyethylenedioxythiophene/polystyrene sulfonate (abbreviated as PEDOT-PSS) (P.VP.A14083, available from H. C. Starck) was spin-coated. Then, this film was dried by heating at 100° C. for 20 minutes to form an electron-blocking layer. The electron-blocking layer had a thickness of 40 nm.

### Coating of Photoelectric Conversion Layer (Bulk Hetero Layer) 24

In 1 ml of chlorobenzene, 20 mg of P3HT (poly-3-hexylthiophene, LISICON SP-001 (trade name), available from Merck) and 14 mg of PCBM ([6,6]-phenyl C₆₁-butyric acid methyl ester, NANOMSPECTRA E-100H (trade name), available from Frontier Carbon) were dissolved to prepare a bulk hetero layer coating solution. This coating solution was spin-coated on the surface of the transparent conductive film or on the electron-blocking layer to form the bulk hetero layer. The rotational speed of the spin coater was 500 rpm, and the dry film thickness was 180 nm.

### Annealing

Thereafter, this sample was heated at 130° C. for 15 minutes using a hot plate.

### Coating of Electron Collection Layer

A coating solution containing a mixture of 20 of titanium tetraisopropoxide and 4 ml of dehydrated ethanol was spin-coated on the bulk hetero layer. The rotational speed of the spin coater was 2000 rpm. This film was dried in the atmosphere for 1 hour to provide an electron collection layer made of amorphous titanium oxide having a thickness of 7 nm.

### Vapor Deposition of Negative Electrode

Aluminum was vapor-deposited to a thickness of 100 nm on the electron collection layer to form the negative electrode 26.

### Formation of Upper Sealing Member

On the sample with the negative electrode formed thereon, a back sheet for sealing solar batteries (a barrier film with an EVA adhesive layer), available from Lintec, was placed and vacuum lamination was performed at 140° C.

In this manner, organic thin-film solar batteries (P-1 to P-6) were produced. For each solar battery (P-1 to P-6), ten samples were produced under the same conditions. The organic thin-film solar batteries P-1 to P-3 and P-6 are Examples 1 to 3 and Example 1-2, and the organic thin-film solar batteries P-4 and P-5 are Comparative Examples 1 and 2.

### Measurement of Power Generation Efficiency

While applying simulated sunlight of AM 1.5 G and 100 mW/cm² using a solar simulator, XES-502S+ELS-100, available from San-Ei Electric Co., Ltd., to the organic thin-film solar batteries (ten samples for each of P-1 to P-6), values of generated current in the voltage range from −0.1V to 1.0V were measured using a source measure unit (SMU2400, available from Keithley). The simulated sunlight was applied to each device through a mask having a 1 cm×1 cm square through hole. The resulting current-voltage characteristics were evaluated using an I-V curve analyzer available from Peccell Technologies, and characteristics parameters were calculated to calculate the power generation efficiency. The results of the measurement are shown in Table 1 below. It should be noted that the calculated power generation efficiency is an average value of good products after removing defective products due to short circuit. Rate of the defective products due to short circuit is also shown in Table 1.

TABLE 1

| | | Transparent | Stripe | | | Percent | Power Generation |
|---|---|---|---|---|---|---|---|
| | Sample | Conductive | Film | Stripe | Stripe | Defective | Efficiency |
| | No. | Film | Thickness | Line Width | Interval | [%] | [%] |
| Example 1 | P-1 | F-1 | 100 nm | 0.5 mm | 4 mm | 0 | 2.3 |
| Example 2 | P-2 | F-2 | 200 nm | 0.5 mm | 4 mm | 10 | 2.4 |
| Example 3 | P-3 | F-3 | 400 nm | 0.5 mm | 4 mm | 50 | 2.4 |
| Comp. Example 1 | P-4 | F-4 | 600 nm | 0.5 mm | 4 mm | 100 | — |
| Comp. Example 2 | P-5 | F-5 | 100 nm | 0.5 mm | 2 mm | 0 | 2 |
| Example 1-2 | P-6 | F-6 | 100 nm | 0.5 mm | 4 mm | 0 | 2.2 |

As can be seen from the results shown in Table 1, the greater the thickness of the vapor-deposited conductive stripe, the greater the percent defective. With respect to the organic thin-film solar battery (P-4) having a thickness of 600 nm, all the devices had short circuit. With respect to the device (P-5) with a stripe interval of 2 mm, the power generation efficiency decreased as the open area ratio decreased. Further, in the case where copper was used as the material forming the conductive stripe (Example 1-2), the same level of advantageous effect as that in the case where silver was used (Example 1) was obtained.

### Examples 4 to 6

### Production of Transparent Conductive Film

Transparent conductive films (F-11 to F-13) were produced in the same manner as the production of the transparent conductive film (F-1) of Example 1, except that the mask was slid during the vapor deposition of silver. The holder of the mask was movable, and the sliding was achieved using a stepper motor for a vacuum chamber. The sliding direction was perpendicular to the stripe in the plane of the mask. The sliding width was 0.05 mm. The film thickness and the line width of the formed conductive stripe was as shown in Table 2. The line width was increased by the sliding width, and the cross-section of the stripe in the perpendicular direction had an isosceles trapezoidal shape where the thickness decreased toward each end.

### Production of Organic Thin-Film Solar Battery

Using the transparent conductive films (F-11 to F-13), organic thin-film solar batteries (P-11 to P-13) of Examples 4 to 6 were produced in the same manner as in Example 1.

### Measurement of Power Generation Efficiency

The percent defective and the power generation efficiency of the organic thin-film solar batteries of Examples 4 to 6 were measured in the same manner as the measurement of the organic thin-film solar battery of Example 1. The results are shown in Table 2.

TABLE 2

| | | Transparent | Stripe | | | Percent | Power Generation |
|---|---|---|---|---|---|---|---|
| | Sample | Conductive | Film | Stripe | Stripe | Defective | Efficiency |
| | No. | Film | Thickness | Line Width | Interval | [%] | [%] |
| Example 4 | P-11 | F-11 | 100 nm | 0.55 mm | 4 mm | 0 | 2.3 |
| Example 5 | P-12 | F-12 | 200 nm | 0.55 mm | 4 mm | 0 | 2.3 |
| Example 6 | P-13 | F-13 | 400 nm | 0.55 mm | 4 mm | 0 | 2.4 |

There was no defective device (short circuit) among the organic thin-film solar batteries of Examples 4 to 6, even in the example having a film thickness of the conductive stripe of 400 nm. The reason of this is believed to be that obtuse corners of the protrusions of the conductive stripe were provided by the sliding. This result indicates that a roll-to-roll film forming process, where the film on which the vapor deposition is performed is always moving during the vapor deposition, can provide a conductive stripe that is less likely cause the short circuit defect than a conductive stripe formed by a stationary film forming process.

### Comparative Examples 3 to 5

### Production of Transparent Conductive Film

Transparent conductive films (F-21 to F-23) of Comparative Examples 3 to 5 were produced by forming the conductive stripe in a different manner from those in Examples 1 to 6.

In each comparative example, silver was vapor-deposited to the thickness shown in Table 3 on the entire surface of a PET film. Then, a negative photoresist was applied to the silver film, and pattern exposure and development were performed to form a stripe resist pattern. Etching was performed using dilute nitric acid, and then the resist was removed to form the conductive stripe.

Subsequently, the transparent conductive layer was formed in the same manner as in Example 1 to produce transparent conductive films (F-21 to F-23) of Comparative Examples 3 to 5. The cross-section of the stripe in the perpendicular direction was a rectangle with sharp corners.

### Production of Organic Thin-Film Solar Battery

Using the transparent conductive films (F-21 to F-23), organic thin-film solar batteries (P-21 to P-23) of Comparative Examples 3 to 5 were produced in the same manner as the production of the organic thin-film solar battery of Example 1.

### Measurement of Power Generation Efficiency

The percent defective and the power generation efficiency of the organic thin-film solar batteries of Comparative Examples 3 to 5 were measured in the same manner as the measurement of the organic thin-film solar battery of Example 1. The results are shown in Table 3.

TABLE 3

| | | Transparent | Stripe | | | Percent | Power Generation |
|---|---|---|---|---|---|---|---|
| | Sample | Conductive | Film | Stripe | Stripe | Defective | Efficiency |
| | No. | Film | Thickness | Line Width | Interval | [%] | [%] |
| Comp. Example 3 | P-21 | F-21 | 100 nm | 0.5 mm | 4 mm | 20 | 2.2 |
| Comp. Example 4 | P-22 | F-22 | 200 nm | 0.5 mm | 4 mm | 60 | 2.3 |
| Comp. Example 5 | P-23 | F-23 | 400 nm | 0.5 mm | 4 mm | 100 | — |

There were defective devices (short circuit) among the organic thin-film solar batteries of Comparative Examples 3 to 5, even in the example having a thickness of the conductive stripe of 100 nm. In the examples having a thickness of the conductive stripe of 400 nm, all the samples were defective. This is believed to be because of the sharp corners of the protrusions of the conductive stripe. This result indicates that, even when the same vapor deposition process is used, forming the conductive stripe by etching is likely to cause the short circuit defect and is not preferred.

### Example 7 and Comparative Examples 6 and 7

### Production of Transparent Conductive Film

Each of transparent conductive films (F-31 to F-33) was produced by forming the conductive stripe on a PET film having a thickness of 180 μm, and then forming the conductive polymer layer on the conductive stripe.

### Formation of Conductive Stripe

Each piece of PET film cut into a size of 50 mm×50 mm and a mask for a 50 mm×50 mm substrate were set in a vacuum deposition apparatus, and silver was vapor-deposited to a thickness of 100 nm using resistance heating. The vapor deposition was upward deposition, and the deposition pattern was a parallel stripe having a line width of 0.5 mm, a line length of 30 mm and a line interval of 8 mm. To form this pattern, the mask made of stainless-steel and having a thickness of 0.3 mm was set below the PET film in close contact with the PET film.

Subsequently, contact between ends of the conductive stripe was provided using a silver paste.

### Formation of Conductive Polymer Layer

On the surface of each of the thus formed films, an aqueous dispersion of a PEDOT-PSS having different specific resistance shown in Table 4 was spin-coated. Then, this film was dried by heating at 110° C. for 20 minutes to form a conductive polymer layer. The thickness of the conductive polymer layer was 100 nm. In this manner, Example 7 (F-31) and Comparative Examples 6 and 7 (F-32 and 33) were obtained.

Separately from this, the specific resistance of PEDOT-PSS was measured in the same manner as the measurement of the conductive polymer layer of the transparent conductive film of Example 1. As a result, ORGACON S-305 available from Agfa was found to have a specific resistance of 2.2×10⁻³ Ωcm, CLEVIOS PH-500 available from H. C. Starck was found to have a specific resistance of 1.0×10⁻² Ωcm, and a transparent conductive polymer composed of CLEVIOS PH-500 available from H. C. Starck with 1 mass % of dimethylsulfoxide (DMSO) added thereto was found to have a specific resistance of 6.0×10⁻³ Ω·cm.

### Production of Organic Thin-Film Solar Battery

Using the thus formed transparent conductive films (F-31 to F-33), organic thin-film solar batteries (2-31 to 2-33) were produced in the same manner as the production of the organic thin-film solar battery of Example 1.

### Measurement of Power Generation Efficiency

The power generation efficiency of each of the organic thin-film solar batteries of Example 7 and Comparative Examples 6 and 7 was measured in the same manner as the measurement of the organic thin-film solar battery of Example 1, except that the exposure area to the light was 4 cm² (a 2 cm×2 cm square). The results are shown in Table 4.

TABLE 4

| | | | | | | | | Power |
|---|---|---|---|---|---|---|---|---|
| | | Transparent | Stripe | | | Transparent | Specific | Generation |
| | Sample | Conductive | Film | Stripe | Stripe | Conductive | Resistance | Efficiency |
| | No. | Film | Thickness | Line Width | Interval | Film Material | [Ωcm] | [%] |
| Example 7 | P-31 | F-31 | 100 nm | 0.5 mm | 8 mm | S305 | 2.2 × 10⁻³ | 2.1 |
| Comp. | P-32 | F-32 | 100 nm | 0.5 mm | 8 mm | PH-500 | 1.0 × 10⁻² | 1.5 |
| Example 6 | | | | | | | | |
| Comp. | P-33 | F-33 | 100 nm | 0.5 mm | 8 mm | PH-500 + | 6.0 × 10⁻³ | 1.7 |
| Example 7 | | | | | | DMSO | | |

The sample P-31 (Example 7) using the transparent conductive material having a specific resistance of 2.2×10⁻³ Ωcm had higher power generation efficiency and provided a more preferable result than the sample P-32 (Comparative Example 6) using the transparent conductive material having a specific resistance of 1.0×10⁻² Ωcm and the sample P-33 (Comparative Example 7) using the transparent conductive material having a specific resistance of 6.0×10⁻³ Ωcm.

### Examples 8 and 9

### Production of Transparent Conductive Film

A transparent conductive film (F-41) was produced by forming the conductive stripe and the bus lines on a PET film having a thickness of 180 μm, and forming the conductive polymer layer thereon. Further, a transparent conductive film (F-42) was produced in the same manner, except that the bus lines were not provided, for comparison.

### Formation of Conductive Stripe

A piece of PET film cut into a size of 100 mm×100 mm and a mask for a 100 mm×100 mm substrate were set in a vacuum deposition apparatus, and silver was vapor-deposited to a thickness of 100 nm using resistance heating. The vapor deposition was upward deposition, and the deposition pattern was a parallel stripe having a line width of 0.3 mm, a line length of 90 mm and a line interval of 4 mm. To form this pattern, the mask made of stainless-steel and having a thickness of 0.3 mm was set below the PET film in close contact with the PET film.

Subsequently, contact between ends of the conductive stripe was provided using a silver paste.

### Formation of Bus Lines

On the conductive stripe, two bus lines having a line width of 2 mm and a line interval of 40 mm, which were perpendicular to the conductive stripe, were formed. Contact between ends of these adjacent bus lines and contact between ends of the bus lines and ends of the conductive stripe were provided using a silver paste (F-41). On the other hand, Example 9 (F-42) was not provided with the bus lines.

### Formation of Conductive Polymer Layer

On the surface of each of the thus formed films, the conductive polymer layer was formed in the same as in Example 1 to provide transparent conductive films of Example 8 (F-41) and Example 9 (F-42)

### Production of Organic Thin-Film Solar Battery

Using the thus formed transparent conductive films (F-41 to F-42), organic thin-film solar batteries (P-41 to P-42) of Examples 8 and 9 were produced in the same manner as in Example 1.

### Measurement of Power Generation Efficiency

The power generation efficiency of each of the organic thin-film solar batteries of Examples 8 and 9 was measured in the same manner as the measurement of the organic thin-film solar battery of Example 1, except that the exposure area to the light was 64 cm² (a 8 cm×8 cm square). The results are shown in Table 5.

TABLE 5

| | | | | | | | | Power |
|---|---|---|---|---|---|---|---|---|
| | | Transparent | Stripe | | | | | Generation |
| | Sample | Conductive | Film | Stripe | Stripe | | Exposure | Efficiency |
| | No. | Film | Thickness | Line Width | Interval | Bus Lines | Area | [%] |
| Example 8 | P-41 | F-41 | 100 nm | 0.3 mm | 4 mm | provided | 64 cm² | 2.3 |
| Example 9 | P-42 | F-42 | 100 nm | 0.3 mm | 4 mm | not provided | 64 cm² | 2 |

### Example 10

### Organic EL Device

On the transparent conductive film of the invention produced in Example 1, the following organic compound layers, each having the thickness shown below, were formed by vacuum deposition in the order shown below:

(a first hole-transporting layer)

copper phthalocyanine having a film thickness of 10 nm;

(a second hole-transporting layer)

N,N′-diphenyl-N,N′-dinaphthylbenzidine having a film thickness of 40 nm;

(a light-emitting layer/electron-transporting layer)

tris(8-hydroxyquinolinato)aluminum having a film thickness of 60 nm;

(an electron-injection layer)

lithium fluoride having a film thickness of 1 nm; and

(a negative electrode)

aluminum having a film thickness of thickness 100 nm.

Further, a silicon nitride film having a thickness of 5 μm was deposited by parallel-plate CVD to produce an organic EL device. The produced device was transferred into a nitrogen-purged glovebox (dew point: −60° C.) without exposing the device to the atmosphere.

### Evaluation of Organic EL Device

To the organic EL device in the glovebox immediately after the production, a voltage of 7 V was applied using a source measure unit (SMU2400, available from Keithley) to make the device emit light. The state of the light-emission surface was observed, and it was confirmed that this device provided good light emission without unevenness at the stripe openings.

What is claimed is:

1. A transparent conductive film comprising:
a plastic support;
a conductive stripe formed on the plastic support by a mask deposition process, the conductive stripe including a plurality of conductive lines made of a metal or an alloy having a film thickness of not less than 50 nm and not greater than 500 nm and a line width of not less than 0.3 mm and not greater than 1 mm in plan view and being arranged at an interval of not less than 3 mm and not greater than 20 mm; and
a transparent conductive material layer formed to cover the plastic support and the conductive stripe, the transparent conductive material having a specific resistance of not greater than 4×10⁻³Ω·cm and a film thickness of not less than 20 nm and not greater than 500 nm.

2. The transparent conductive film as claimed in claim 1, wherein the conductive lines are made of silver or an alloy containing silver.

3. The transparent conductive film as claimed in claim 1, wherein the conductive lines are made of copper or an alloy containing copper.

4. The transparent conductive film as claimed in claim 1, wherein the conductive lines have a film thickness of not less than 100 nm and not greater than 300 nm.

5. The transparent conductive film as claimed in claim 1, wherein the conductive lines of the conductive stripe are arranged at an interval of not less than 3 mm and not greater than 10 mm in plan view.

6. The transparent conductive film as claimed in claim 1, wherein the conductive stripe has an open area ratio of not less than 80% and not greater than 95%.

7. The transparent conductive film as claimed in claim 1, further comprising a bus line that is in contact with the conductive stripe and has a line width of not less than 1 mm and not greater than 5 mm.

8. The transparent conductive film as claimed in claim 7, wherein the bus line comprises a plurality of bus lines, an interval between the bus lines is not less than 40 mm and not greater than 200 mm, and the bus lines are perpendicular to the conductive stripe.

9. The transparent conductive film as claimed in claim 1, wherein the transparent conductive material layer is made of a transparent conductive polymer or a silver nanowire containing polymer.

10. The transparent conductive film as claimed in claim 9, wherein the transparent conductive material layer is made of a doped polyethylenedioxythiophene.

11. A flexible organic electronic device comprising:
a first electrode comprising the transparent conductive film as claimed in claim 1; and
a functional layer and a counter electrode formed in this order on the first electrode.

12. An organic thin-film solar battery comprising:
a first electrode comprising the transparent conductive film as claimed in claim 1; and
a photoelectric conversion layer and a counter electrode formed in this order on the first electrode.

13. The organic thin-film solar battery as claimed in claim 12, further comprising an electron collection layer disposed between the photoelectric conversion layer and the counter electrode.

14. The organic thin-film solar battery as claimed in claim 13, wherein the electron collection layer comprises a transparent inorganic oxide layer.

15. The organic thin-film solar battery as claimed in claim 14, wherein the transparent inorganic oxide layer contains titanium oxide or zinc oxide.

16. A method of producing a transparent conductive film, the method comprising the steps of:
providing, on a roll of plastic support, a conductive stripe that is parallel to the longitudinal direction of the roll by a mask deposition process; and
forming a transparent conductive material layer that covers the plastic support and the conductive stripe,
wherein the steps are performed in this order.

17. A method of producing a transparent conductive film, the method comprising the steps of:
providing, on a roll of plastic support, a conductive stripe that is parallel to the longitudinal direction of the roll by a mask deposition process;
providing a bus line that is perpendicular to the conductive stripe; and
forming a transparent conductive material layer that covers the conductive stripe and the bus line,
wherein the steps are performed in this order.

18. A method of producing a transparent conductive film, the method comprising the steps of:
providing, on a roll of plastic support, a bus line that is parallel to the width direction of the roll;
providing a conductive stripe that is perpendicular to the bus line by a mask deposition process; and
forming a transparent conductive material layer that covers the bus line and the conductive stripe,
wherein the steps are performed in this order.
